(19) United States
(12) Patent Application Publication
(10) Pub. No.: US 2016/0234963 A1
(43) Pub. Date: Aug. 11, 2016

(54) ENCLOSURES AND METHODS FOR REMOVING HYDROGEN GAS FROM ENCLOSURES

(71) Applicant: Emerson Network Power, Energy Systems, North America, Inc., Warrenville, IL (US)

(72) Inventors: Akshay Dinesh SHAH, Maharashtra (IN); Rakesh Mahaling MALI, Maharashtra (IN)

(21) Appl. No.: 15/015,900

(22) Filed: Feb. 4, 2016

(30) Foreign Application Priority Data
Feb. 10, 2015 (IN) 433/MUM/2015

(51) Int. Cl. H05K 7/20; H01M 2/12; H01M 2/10

(52) U.S. Cl. CPC H05K 7/20127; H01M 2/1022; H01M 2/1264; H01M 2220/30

(57) ABSTRACT

An enclosure includes a battery chamber for housing one or more rechargeable batteries capable of releasing hydrogen gas over time, a ventilation chamber positioned above the battery chamber, and a wall extending between the battery chamber and the ventilation chamber. The battery chamber includes an inlet for allowing air to enter the battery chamber. The wall includes one or more perforations to allow hydrogen gas released by the one or more rechargeable batteries to pass from the battery chamber into the ventilation chamber. The ventilation chamber includes at least one exterior wall having one or more perforations to allow the hydrogen gas in the ventilation chamber to exit the enclosure. Other example enclosures and methods of exhausting hydrogen gas from enclosures are also disclosed.

### CROSS-REFERENCE TO RELATED APPLICATION

This application claims the benefit and priority of Indian Patent Application No. 433/MUM/2015 filed Feb. 10, 2015. The entire disclosure of the above application is incorporated herein by reference.

### FIELD

The present disclosure relates to enclosures and methods for removing hydrogen gas from enclosures.

### BACKGROUND

This section provides background information related to the present disclosure which is not necessarily prior art.

Enclosures may house components that release undesirable gases. For example, some batteries release hydrogen gas when recharging. This hydrogen gas may cause explosions when, for example, the concentration of hydrogen gas in the cabinet rises above about four percent. Typically, enclosures include one or more active systems (e.g., fans, etc.), perforations, etc. to exhaust the hydrogen gas.

### SUMMARY

This section provides a general summary of the disclosure, and is not a comprehensive disclosure of its full scope or all of its features.

According to one aspect of the present disclosure, an electronic equipment enclosure includes a battery chamber, an equipment chamber positioned above the battery chamber, a ventilation chamber positioned between the battery chamber and the equipment chamber; and a wall extending between the battery chamber and the ventilation chamber. The battery chamber is configured to house one or more rechargeable batteries capable of releasing hydrogen gas over time. The battery chamber includes an inlet for allowing air to enter the battery chamber. The equipment chamber is configured to house at least one electrical component. The wall includes one or more perforations to allow hydrogen gas released by the one or more rechargeable batteries to pass from the battery chamber into the ventilation chamber. The ventilation chamber includes at least one side wall having one or more perforations to allow the hydrogen gas in the ventilation chamber to exit the enclosure.

According to another aspect of the present disclosure, an enclosure includes a battery chamber, a ventilation chamber positioned above the battery chamber, and a wall extending between the battery chamber and the ventilation chamber. The battery chamber is configured to house one or more rechargeable batteries capable of releasing hydrogen gas over time. The battery chamber includes an inlet for allowing air to enter the battery chamber. The ventilation chamber includes at least one baffle to restrict water from entering the battery chamber. The wall includes one or more perforations to allow hydrogen gas released by the one or more rechargeable batteries to pass from the battery chamber into the ventilation chamber. The ventilation chamber includes at least one exterior wall having one or more perforations to allow the hydrogen gas in the ventilation chamber to exit the enclosure.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a sectional view of an enclosure including a battery chamber, a ventilation chamber and a wall extending between the battery chamber and the ventilation chamber according to one example embodiment of the present disclosure.

FIG. 2 is a sectional view of the enclosure of FIG. 1 with a heat management system adjacent a side wall of the battery chamber according to another example embodiment.

FIG. 3 is a sectional view of an enclosure having a battery chamber, an equipment chamber, and a ventilation chamber positioned between the battery chamber and the equipment chamber according to yet another example embodiment.

FIG. 4 is a sectional view of the enclosure of FIG. 3 with a heat management system according to another example embodiment.

FIG. 5 is a sectional view of the enclosure of FIG. 3 with baffles in the ventilation chamber according to yet another example embodiment.

FIG. 6 is a sectional view of a ventilation chamber employable in any of the enclosures of FIG. 1-5 according to another example embodiment.

FIG. 7 is a perspective view of a ventilation chamber employable in any of the enclosures of FIG. 1-5 according to yet another example embodiment.

FIG. 8 is a perspective view of a top wall for the ventilation chamber of FIG. 7.

FIG. 9 is a perspective view of a side joint structure of the ventilation chamber of FIG. 7.

Corresponding reference numerals indicate corresponding parts or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

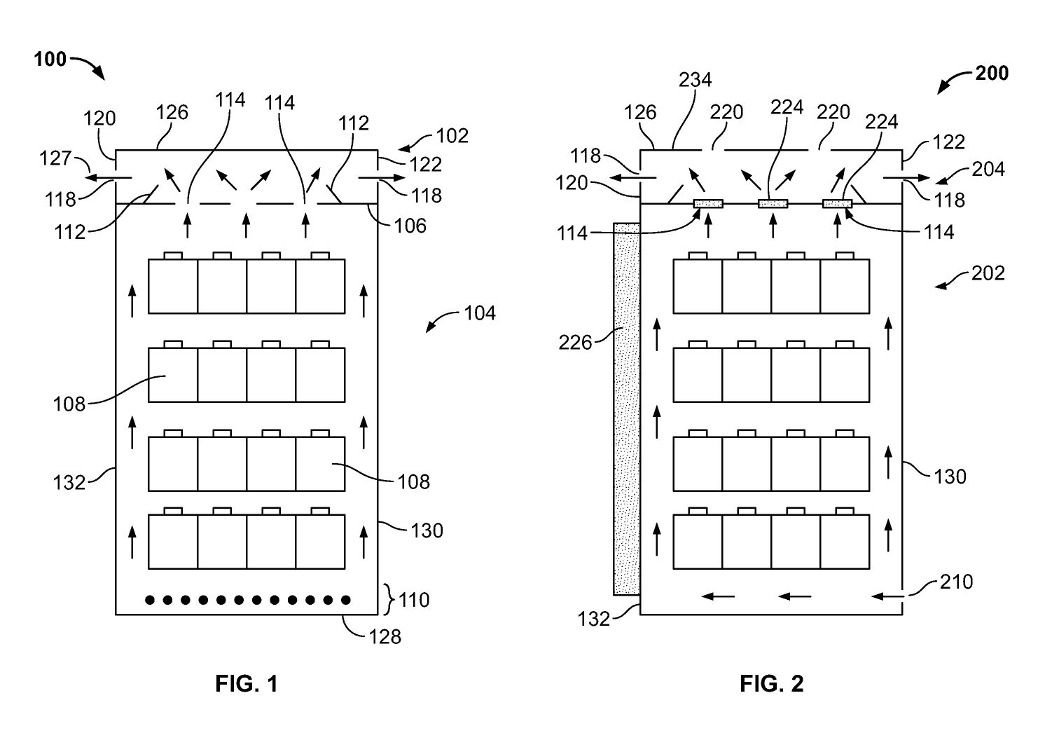

An enclosure according to one example embodiment of the present disclosure is illustrated in FIG. 1, and indicated generally by reference number 100. As shown in FIG. 1, the enclosure 100 includes a battery chamber 102, a ventilation chamber 104 positioned above the battery chamber 102, and a wall 106 extending between the battery chamber 102 and the ventilation chamber 104. The battery chamber 102 is configured to house one or more rechargeable batteries 108 capable of releasing hydrogen gas over time. The battery chamber 102 includes an inlet 110 for allowing air to enter the battery chamber 102. The ventilation chamber 104 includes at least one baffle 112 to restrict water from entering the battery chamber 102. The wall 106 includes one or more perforations 114 to allow hydrogen gas released by the one or more rechargeable batteries 108 to pass from the battery chamber 102 into the ventilation chamber 104. The ventilation chamber 104 includes at least one exterior wall 120, 122 having one or more perforations 118 to allow the hydrogen gas in the ventilation chamber 104 to exit the enclosure 100.

By employing a ventilation chamber above a battery chamber and perforations in walls between the ventilation chamber and battery chamber, hydrogen gas released from rechargeable batteries may be able to naturally exhaust from an enclosure. For example, the enclosure may outgas hydrogen without one or more active cooling systems (e.g., fans, etc.) and/or some passive cooling systems (e.g., a large number of vents, etc.) which may cause turbulence, increased temperatures, increased contaminants (e.g., water, dust, insects, etc.) within the enclosure, etc. As such, the enclosure may efficiently exhaust hydrogen gas to maintain a suitable concentration of hydrogen gas. In some embodiments, the concentration of hydrogen gas may be maintained at (and in some cases below) about one percent.

The perforations 114, 118 may be positioned in the walls to allow the hydrogen gas to exhaust from the enclosure 100 naturally. For example, and as shown in FIG. 1, the perforations 118 are positioned above the perforations 114 of the wall 106 extending between the chambers 102, 104. This configuration allows the hydrogen gas which is less dense and therefore lighter than the surrounding air in the enclosure 100 to rise towards the top portion of the ventilation chamber 104 passing through the lower positioned perforations 114 (relative to the perforations 118). As the hydrogen gas continues to rise, it then can pass through the higher positioned perforations 118 (relative to the perforations 114) and exit the enclosure 100.

As shown in FIG. 1, the ventilation chamber 104 may be defined by multiple external walls and one or more internal walls. For example, the ventilation chamber 104 is defined at least by side external walls (of which walls 120, 122 are shown), the wall 106, and a top external wall 126 (e.g., a ceiling) opposing the wall 106. In the example embodiment of FIG. 1, each side wall 120, 122 includes one perforation 118 to allow the hydrogen gas in the ventilation chamber 104 to exit the enclosure 100 as indicated by the arrows 127 of FIG. 1.

Similarly, the battery chamber 102 may be defined by multiple external walls and one or more internal walls. As shown in the example of FIG. 1, the battery chamber 102 is defined by a bottom external wall 128 (e.g., a floor, etc.), the wall 106, and side external walls (of which walls 130, 132 are shown) extending between the wall 106 and the bottom wall 128. Thus, in the example of FIG. 1, the battery chamber 102 and the ventilation chamber 104 share the wall 106 extending therebetween.

Alternatively, the battery chamber 102 and the ventilation chamber 104 may include separate walls coupled together to form a wall extending between the battery chamber 102 and the ventilation chamber 104. In such examples, each separate wall may include aligned perforations to allow hydrogen gas released by the rechargeable batteries 108 to pass from the battery chamber 102 into the ventilation chamber 104 as explained above.

Furthermore, the example ventilation chamber 104 of FIG. 1 includes two baffles 112 for restricting water from entering the battery chamber 102. In particular, the baffles 112 each include a slanted portion extending from the top side of the shared wall 106 inside the ventilation chamber 104. For example, the baffles 112 may extend inwardly from the shared wall 106 at a defined angle (e.g., about 45 degrees as shown in FIG. 1, about 60 degrees, about 90 degrees, etc.). Additionally, and as shown in FIG. 1, each baffle 112 is adjacent an outermost perforation 114 of the shared wall 106. As such, water and/or other contaminants that may enter the ventilation chamber 104 via the perforations 118 may be trapped between the baffles 112, the wall 106, and the walls 120, 122 and thus restricted from entering the battery chamber 102 through the perforations 114. In such cases, the ventilation chamber 104 may include a drainage system to remove the water and/or other contaminants.

As explained above, the battery chamber 102 includes the inlet 110 for allowing air to enter the enclosure 100. For example, and as shown in FIG. 1, one of the side walls (e.g., the back side wall extending between the side walls 130, 132) of the battery chamber 102 includes the inlet 110 adjacent the bottom wall 128. In the particular example of FIG. 1, the inlet 110 includes twelve perforations for allowing air (e.g., ambient air, etc.) to enter the enclosure 100.

Although the inlet 110 of FIG. 1 includes twelve perforations, it should be apparent that more or less perforations and/or another suitable inlet may be employed to allow a sufficient amount of air to enter the battery chamber 102 to assist in exhausting the hydrogen gas from the enclosure as explained above. Additionally, although FIG. 1 illustrates the back side wall as including the inlet 110, it should be apparent to those skilled in the art that one or more other walls (e.g., the side walls 130, 132, the bottom wall 128, etc.) of the battery chamber 102 may include one or more inlets in addition and/or alternative to the inlet 110.

The rechargeable batteries 108 of FIG. 1 are shown as battery stacks including multiple batteries. For example, and as shown in FIG. 1, the enclosure 100 includes four rechargeable battery stacks each including multiple batteries. The rechargeable batteries 108 may be used to provide backup power to a load when a primary power source (e.g., rectifiers, etc.) is unable to provide adequate power. Although the enclosure 100 is shown to include four rechargeable battery stacks 108, it should be apparent that more or less rechargeable batteries stacks may be employed without departing from the scope of the disclosure.

Additionally, although FIG. 1 illustrates the shared wall 106 as including three perforations 114 and the walls 120, 122 as including one perforation 118, it should be apparent that each wall may include more or less perforations without departing from the scope of the disclosure. For example, the wall 120 may include two perforations, the wall 122 may include three perforations, and the shared wall 106 may include five perforations.

In some embodiments, the enclosure may include one or more thermal management systems. For example, FIG. 2 illustrates another example enclosure 200 similar to the enclosure 100 of FIG. 1. For example, the enclosure 200 includes a battery chamber 202 and a ventilation chamber 204 substantially similar to the battery chamber 102 and the ventilation chamber 104 of FIG. 1. The enclosure 200 of FIG. 2, however, includes a thermal management system 226 adjacent the side wall 132 of the battery chamber 202. The thermal management system 226 may include, for example, a shroud, one or more heat generating components (e.g., heaters, etc.), one or more heat dissipating components (e.g., heat exchangers, thermoelectric (TEC) assemblies, fans, heat sinks, etc.), etc. In some embodiments, the heat management system 226 may be a part of a door for the enclosure 200.

Although FIG. 2 illustrates the thermal management system 226 as being adjacent the side wall 132, it should be apparent that a portion of or the entire thermal management system 226 may be adjacent another suitable wall and/or area of the enclosure 200 if desired.

As shown in FIG. 2, the enclosure 200 includes perforations on various walls. For example, the wall 126 includes two perforations 220 and the walls 120, 122 include one perforation 118 as explained above. Additionally, and as shown in FIG. 2, the enclosure 200 includes at least one perforation 210 (e.g., sometimes referred to as an inlet) on the side wall 130 of the battery chamber 202 allowing air to enter the battery chamber 202 as explained above.

In the example of FIG. 2, the enclosure 200 includes a filter 224 adjacent each perforation 114 of the shared wall 106 extending between the chambers 102, 104. The filters 224 allow the hydrogen gas to pass and restrict water and/or other contaminants from entering the battery chamber 202. The filters 224 may be any suitable filter. Additionally, although FIG. 2 illustrates a filter 224 adjacent each perforation 114, it should be apparent one or more perforations 114 may not include a filter or the like if desired. Further, in some embodiments, filters (e.g., similar to the filters 224, etc.) may be positioned adjacent the perforations 118 and/or the perforations 220 to allow the hydrogen gas to pass and restrict water and/or other contaminants from entering the ventilation chamber 204.

In some embodiments, the ventilation chamber and/or the battery chamber may include a solar shield adjacent to any one or more of its exterior walls. For example, and as shown in FIG. 2, the ventilation chamber 204 includes a solar shield 234 adjacent the top exterior wall 126 and/or adjacent one or both of the side walls 120, 122. The solar shield 234 may be any suitable shield that reflects at least some solar energy while allowing the hydrogen gas to exit from the enclosure 200. For example, the solar shield 234 may be a component of one or more ventilation chamber walls. In such cases, the ventilation chamber wall(s) may be formed of a particular material to reflect solar energy. In other examples, the solar shield may include a material (e.g., a film, paint, etc.) coupled to the ventilation chamber wall(s). For example, the wall and/or the solar shield may be formed of aluminum (e.g., anodized aluminum, etc.), a fiberglass material, and/or another suitable material that has a desired reflection coefficient (e.g., a ratio of the radiation flux reflected by a surface to the incident radiation flux).

Further, and as shown in FIGS. 1 and 2, the enclosures 100, 200 include the rechargeable battery stacks 108 but no other electronic equipment. Thus, the enclosures 100, 200 of FIGS. 1 and 2 may be considered a battery enclosure. Additionally and/or alternatively, the enclosure 100 may include one or more other components including, for example, control circuits, power components (e.g., rectifiers, converters, etc.), etc. In such examples, the enclosure may be considered an electronic equipment enclosure.

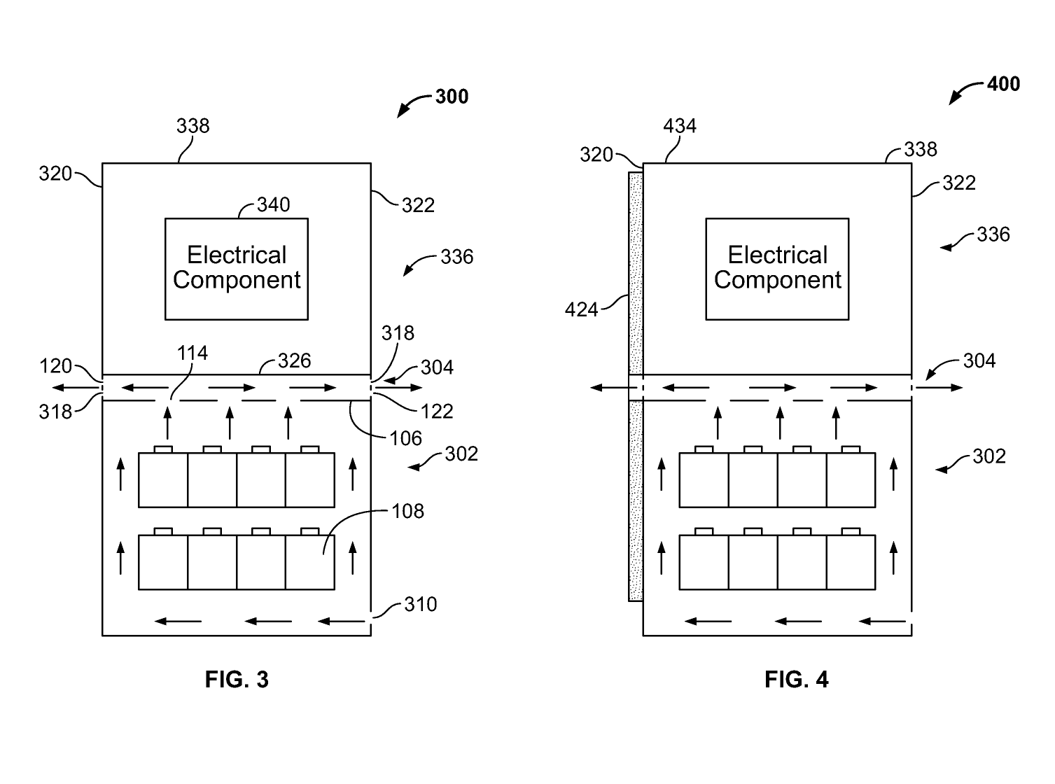

For example, FIG. 3 illustrates an electronic equipment enclosure 300 having a battery chamber 302, an equipment chamber 336 positioned above the battery chamber 302, and a ventilation chamber 304 positioned between the battery chamber 302 and the equipment chamber 336. The battery chamber 302 is substantially similar to the battery chamber 102 of FIG. 1 and the ventilation chamber 304 is substantially similar to the ventilation chamber 104 of FIG. 1 but without the baffles 112. For example, the battery chamber 302 includes various walls (e.g., the wall 106, etc.), houses two stacks of the rechargeable batteries 108 capable of releasing hydrogen gas over time, and an inlet 310 (e.g., similar to the inlet 210 of FIG. 2) for allowing air to enter the chamber 302.

Similar to the enclosure 100 of FIG. 1, the enclosure 300 of FIG. 3 includes the ventilation chamber 304 positioned above the battery chamber 302 and the wall 106 extending between the battery chamber 302 and the ventilation chamber 304. The ventilation chamber 304 of FIG. 3 is defined by the side walls 120, 122, the wall 106, and a top wall 326. As shown in FIG. 3, each side wall 120, 122 includes two perforations 318 for allowing air, hydrogen gas, etc. to escape.

As shown in FIG. 3, the equipment chamber 336 has multiple walls for defining an interior for housing electrical component(s) 340. For example, the equipment chamber 336 includes a top wall 338, the wall 326, and side walls (e.g., walls 320, 322, etc.) extending between the walls 326, 338. The electrical component(s) 340 may include, for example, converters, rectifiers, control circuits, etc.

In the example of FIG. 3, the equipment chamber 336 and the ventilation chamber 304 share the wall 326, and the ventilation chamber 304 and the battery chamber 302 share the wall 106 (as explained above). Alternatively, one or more chambers may include separate walls coupled together to form a wall extending between the equipment chamber 336 and the ventilation chamber 304 and/or the battery chamber 302 and the ventilation chamber 304 as explained above.

If hydrogen gas is released from the batteries 108 (e.g., outgassed, etc.), the hydrogen gas may flow into the ventilation chamber 304 via the perforations 114 as explained above. Additionally, negative pressure within the enclosure 300 may be created by allowing air (e.g., ambient air, etc.) to enter the battery chamber 302 via the inlet 310 (as explained above) and flow into the ventilation chamber 304 thereby generating an air flow path to assist in removing the hydrogen gas. After which, the gas and/or air may be exhausted from the enclosure 300 via the perforations 318 of the side walls 120, 122.

In some example embodiments, the equipment chamber 336 may be sealed to protect the electrical component(s) 340 from contaminants (e.g., the hydrogen gas released from the batteries 108, water, etc.). As such, the equipment chamber 336 may be considered a sealed equipment chamber (e.g., environmentally sealed, etc.). In such examples, the chamber 336 may not include cutouts (or the like) that allow a free exchange of air including contaminants to enter. Thus, and as shown in FIG. 3, the wall 326 extending between the equipment chamber 336 and the ventilation chamber 304 does not include perforations or the like. If appropriate, the sealed enclosure may include gaskets, seals, potting, filters (as explained herein), etc. to protect the interior of the cabinet from contaminants (e.g., moisture, dirt, air, dust, etc.).

FIG. 4 illustrates another example electronic equipment enclosure 400 substantially similar to the electronic equipment enclosure 300 of FIG. 3. The electronic equipment enclosure 400 of FIG. 4, however, includes a thermal management system 424 adjacent one side (e.g., side walls) of the equipment chamber 336, the ventilation chamber 304, and the battery chamber 302. The thermal management system 424 of FIG. 4 may be substantially similar to the thermal management system 226 of FIG. 2. The thermal management system 424 of FIG. 4, however, may include perforations or the like to allow hydrogen gas to pass therethrough.

Additionally, the enclosure 400 of FIG. 4 may include one or more solar shields adjacent to any one or more of its exterior walls. For example, the enclosure 400 includes a solar shield 434 adjacent the top exterior wall 338 and/or parts of all side walls (e.g., the side walls 320, 322) of the equipment chamber 336. The solar shield 334 of FIG. 4 may be substantially similar to the solar shield 234 of FIG. 2.

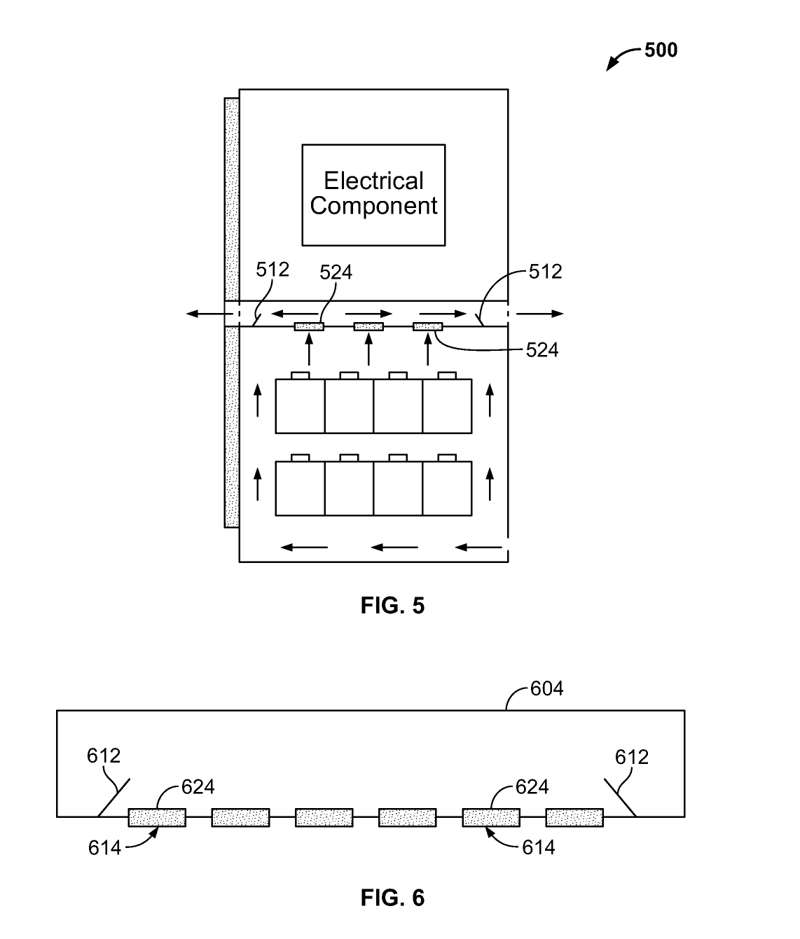

In some embodiments, the enclosure may include one or more baffles and/or filters for restricting water from entering the battery chamber. For example, FIG. 5 illustrates an electronic equipment enclosure 500 substantially similar to the enclosure 400 of FIG. 4, but including two baffles 512 positioned in the ventilation chamber and filters 524 adjacent perforations of the shared wall extending between the battery chamber and the ventilation chamber. The baffles 512 and the filters 524 may be substantially similar to the baffles 112 of FIG. 1 and the filters 224 of FIG. 2.

As explained above, the ventilation chambers disclosed herein may include a shared wall having one or more perforations. For example, the ventilation chambers of FIGS. 1-5 include three perforations. Alternatively, the ventilation chambers may include more or less perforations if desired. For example, FIG. 6 illustrates another ventilation chamber 604 including six perforations 614, six filters 624 adjacent (e.g., covering, etc.) the perforations 614, and two baffles 612 adjacent the outermost perforations 614. The perforations 614, the filters 624, and the baffles 612 may be substantially similar to any one of the other perforations, the filters, and the baffles disclosed herein. The ventilation chamber 604 may be employed in any one of the enclosures of FIG. 1-5.

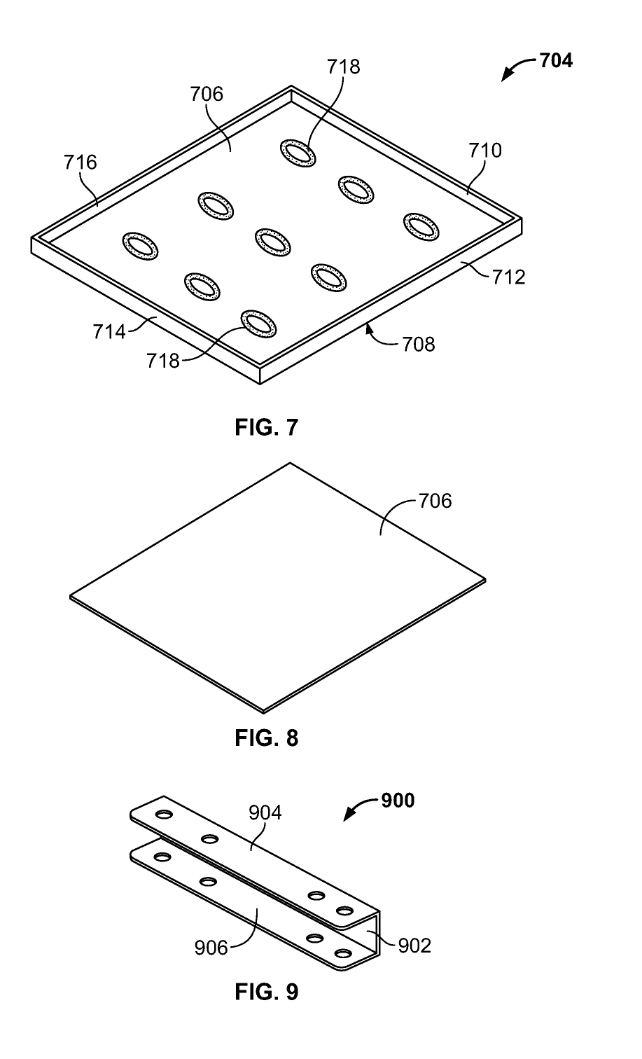

FIG. 7 illustrates another example ventilation chamber 704 including a top wall 706, a bottom wall 708 opposing the top wall 706, and four side walls 710, 712, 714, 716 extending between the walls 706, 708. As shown in FIGS. 7 and 8, the top wall 706 is a solid plate.

The ventilation chamber 704 may be employed in any one of the enclosures of FIG. 1-5. As such, the top wall 706 may be an external top wall of an enclosure if the enclosure does not include an equipment chamber above the ventilation chamber 704. Alternatively, if an enclosure includes an equipment chamber above the ventilation chamber 704, the top wall 706 may be a shared wall between the ventilation chamber 704 and the equipment chamber.

The bottom wall 708 may be positioned between the ventilation chamber 704 and a battery chamber including rechargeable batteries as explained above. As such, the bottom wall 708 includes perforations 718 to allow hydrogen gas released by the rechargeable batteries to pass from the battery chamber into the ventilation chamber 704 as explained above. In the example of FIG. 7, the bottom wall 708 includes nine perforations 718. Alternatively, more or less perforations may be employed without departing from the scope of the disclosure.

Additionally, although not shown, at least one of the side walls 710, 712, 714, 716 and/or the top wall 706 may include one or more perforations to allow the hydrogen gas in the ventilation chamber 704 to exit an enclosure.

FIG. 9 illustrates a bracket 900 including a top wall 904, a bottom wall 906, and a side wall 902 extending between the walls 904, 906. The bracket 900 may be used as a portion of any one of the ventilation chambers disclosed herein. For example, the ventilation chamber 704 may include two brackets 900 extending along opposing sides of the ventilation chamber 704. In such cases, the side wall 902 of each bracket 900 may be part of, the entire portion of, etc. one of the side walls (e.g., walls 710, 712, 714, 716) of the ventilation chamber 704. Additionally, each top wall 904 and bottom wall 906 of the bracket 900 may be coupled to the wall 706 and the wall 708, respectively, of the ventilation chamber 704 via fasteners (e.g., screws, rivets, etc.), weld, etc.

As explained above, hydrogen gas released from rechargeable batteries in an enclosure may be exhausted by passing (e.g., venting, exhausting, etc.) hydrogen gas from a battery chamber of the enclosure to a ventilation chamber of the enclosure via perforations in a wall between the two chambers. The hydrogen gas may be exhausted from the enclosure by passing the hydrogen gas from the ventilation chamber via one or more additional perforations in one or more exterior walls of the ventilation chamber.

As such, the enclosures disclosed herein may provide low cost solutions for exhausting hydrogen outgassed from rechargeable batteries within the enclosures while complying with applicable standards (e.g., Telcordia requirements, etc.). Additionally, the enclosures may efficiently exhaust hydrogen gas without substantially impacting thermal performance of the enclosures.

The enclosures may be deployed outdoors and/or indoors (provided appropriate external ventilation). The enclosures may be used as telecommunications enclosures, battery enclosures, power enclosures, etc. In some embodiments, at least a portion of the enclosures may include environmentally sealed portions (as explained above) depending on the filters, gaskets, seals, potting, etc.

The enclosures and/or chambers disclosed herein may be any suitable material, size, shape, etc. For example, the ventilation chambers may have a height of about 1.5 inches. Alternatively, the ventilation chambers may have a height of more or less than about 1.5 inches if desired. The walls of the chambers may be formed of one continuous piece of material or formed of multiple pieces of material. For example, the walls may be formed of sheet metal, the walls (including portions of) may be defined by equipment housed in the chamber, etc.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An electronic equipment enclosure comprising:
a battery chamber for housing one or more rechargeable batteries capable of releasing hydrogen gas over time, the battery chamber having an inlet for allowing air to enter the battery chamber;
an equipment chamber for housing at least one electrical component, the equipment chamber positioned above the battery chamber;
a ventilation chamber positioned between the battery chamber and the equipment chamber; and
a wall extending between the battery chamber and the ventilation chamber, the wall including one or more perforations to allow hydrogen gas released by the one or more rechargeable batteries to pass from the battery chamber into the ventilation chamber, the ventilation chamber including at least one side wall having one or more perforations to allow the hydrogen gas in the ventilation chamber to exit the enclosure.

2. The enclosure of claim 1 further comprising at least one filter adjacent the one or more perforations of the wall extending between the battery chamber and the ventilation chamber, the at least one filter configured to allow the hydrogen gas to pass and restrict water from entering the battery chamber.

3. The enclosure of claim 1 wherein the ventilation chamber comprises at least one baffle to restrict water from entering the battery chamber.

4. The enclosure of claim 1 wherein the equipment chamber is a sealed equipment chamber.

5. The enclosure of claim 4 wherein the equipment chamber includes a plurality of walls, the enclosure further comprising a solar shield adjacent at least one of the plurality of plurality of walls.

6. The enclosure of claim 5 wherein the ventilation chamber comprises a height of about 1.5 inches.

7. An enclosure comprising:
a battery chamber for housing one or more rechargeable batteries capable of releasing hydrogen gas over time, the battery chamber having an inlet for allowing air to enter the battery chamber;
a ventilation chamber positioned above the battery chamber, the ventilation chamber including at least one baffle to restrict water from entering the battery chamber; and
a wall extending between the battery chamber and the ventilation chamber, the wall including one or more perforations to allow hydrogen gas released by the one or more rechargeable batteries to pass from the battery chamber into the ventilation chamber, the ventilation chamber including at least one exterior wall having one or more perforations to allow the hydrogen gas in the ventilation chamber to exit the enclosure.

8. The enclosure of claim 7 further comprising at least one filter adjacent the one or more perforations of the wall extending between the battery chamber and the ventilation chamber, the at least one filter being configured to allow the hydrogen gas to pass and restrict water from entering the battery chamber.

9. The enclosure of claim 7 wherein the at least one exterior wall includes at least one side wall of the ventilation chamber.

10. The enclosure of claim 7 wherein the equipment chamber includes a plurality of walls, the enclosure further comprising a solar shield adjacent at least one of the plurality of plurality of walls.

11. The enclosure of claim 7 wherein the ventilation chamber comprises a height of about 1.5 inches.

12. The enclosure of claim 8 wherein the at least one exterior wall includes at least one side wall of the ventilation chamber.

13. The enclosure of claim 12 further comprising a solar shield adjacent at least one of the battery chamber and the ventilation chamber.

14. The enclosure of claim 8 further comprising a solar shield adjacent at least one of the battery chamber and the ventilation chamber.

15. The enclosure of claim 9 further comprising a solar shield adjacent at least one of the battery chamber and the ventilation chamber.

16. The enclosure of claim 2 wherein the ventilation chamber comprises at least one baffle to restrict water from entering the battery chamber.

17. The enclosure of claim 16 wherein the equipment chamber includes a plurality of walls, the enclosure further comprising a solar shield adjacent at least one of the plurality of plurality of walls.

18. The enclosure of claim 17 wherein the equipment chamber is a sealed equipment chamber.

19. The enclosure of claim 2 wherein the equipment chamber includes a plurality of walls, the enclosure further comprising a solar shield adjacent at least one of the plurality of plurality of walls.

20. The enclosure of claim 3 wherein the equipment chamber includes a plurality of walls, the enclosure further comprising a solar shield adjacent at least one of the plurality of plurality of walls.
